(19) United States
(12) Patent Application Publication
(10) Pub. No.: US 2021/0252643 A1
(43) Pub. Date: Aug. 19, 2021

(54) Method and Apparatus for Surface Structuring to Increase Emissivity

(71) Applicants: Jian Liu, Saratoga, CA (US); Shuang Bai, Saratoga, CA (US)

(72) Inventors: Jian Liu, Saratoga, CA (US); Shuang Bai, Saratoga, CA (US)

(73) Assignee: PolarOnyx, Inc., San Jose, CA (US)

(21) Appl. No.: 16/791,892

(22) Filed: Feb. 14, 2020

(51) Int. Cl. B23K 26/352; H01S 3/094

(52) U.S. Cl. CPC B23K 26/352; B82Y 40/00; H01S 3/094042

(57) ABSTRACT

Methods and systems for surface structuring to increase emissivity of one or more samples comprising: generating electromagnetic radiation from a femtosecond fiber laser, wherein the electromagnetic radiation comprises a wavelength, a pulse repetition rate, a pulse width, a pulse energy, and an average power; coupling the electromagnetic radiation from the femtosecond fiber laser to an autofocusing scanner, wherein the autofocusing scanner is configured to scan and focus the electromagnetic radiation onto the one or more samples; and using a computer to adjust the pulse repetition rate and the pulse energy of the femtosecond fiber laser and to control the autofocusing scanner to scan and focus the electromagnetic radiation onto the one or more samples to fabricate micro spikes onto the surface of the one or more samples in order to increase the emissivity of the one or more samples. Other embodiments are described and claimed.

### I. STATEMENT REGARDING FEDERALLY SPONSORED RESEARCH

The U.S. Government has a paid-up license in this invention and the right in limited circumstances to require the patent owner to license others on reasonable terms as provided for by the terms of the NASA SBIR contract number 80NSSC19C0269.

### II. BACKGROUND

The invention relates generally to the field of surface structuring to achieve high emissivity. More particularly, the invention relates to a method and apparatus for creating coated surface structures in order to increase emissivity and resistance to harsh environments.

### III. SUMMARY

In one respect, disclosed is a method for surface structuring to increase emissivity of one or more samples comprising: generating electromagnetic radiation from a femtosecond fiber laser, wherein the electromagnetic radiation comprises a wavelength, a pulse repetition rate, a pulse width, a pulse energy, and an average power; coupling the electromagnetic radiation from the femtosecond fiber laser to an autofocusing scanner, wherein the autofocusing scanner is configured to scan and focus the electromagnetic radiation onto the one or more samples; and using a computer to adjust the pulse repetition rate and the pulse energy of the femtosecond fiber laser and to control the autofocusing scanner to scan and focus the electromagnetic radiation onto the one or more samples to fabricate micro spikes onto the surface of the one or more samples in order to increase the emissivity of the one or more samples.

In another respect, disclosed is an apparatus for surface structuring to increase emissivity of one or more samples comprising: a femtosecond fiber laser configured to generate electromagnetic radiation comprising a wavelength, a pulse repetition rate, a pulse width, a pulse energy, and an average power; an autofocusing scanner configured to receive the electromagnetic radiation from the femtosecond fiber laser and to scan and focus the electromagnetic radiation onto the one or more samples; and a computer configured to adjust the pulse repetition rate and the pulse energy of the femtosecond fiber laser and to control the autofocusing scanner to scan and focus the electromagnetic radiation onto the one or more samples to fabricate micro spikes onto the surface of the one or more samples in order to increase the emissivity of the one or more samples.

Numerous additional embodiments are also possible.

### IV. BRIEF DESCRIPTION OF THE DRAWINGS

Other objects and advantages of the invention may become apparent upon reading the detailed description and upon reference to the accompanying drawings.

FIG. 1 is a schematic illustration of an apparatus for surface structuring to increase emissivity, in accordance with some embodiments.

FIG. 2 is a schematic diagram illustrating the light trapping mechanism resulting from the surface structuring to increase emissivity, in accordance with some embodiments.

FIG. 3 is a schematic illustration of the surface structuring to increase emissivity, in accordance with some embodiments.

FIG. 4 is a schematic illustration of the surface structuring to increase emissivity, in accordance with some embodiments.

FIG. 5 is a schematic illustration of the surface structuring and concurrent coating to increase emissivity and resistance to harsh environments, in accordance with some embodiments.

FIG. 6 is a schematic illustration of a method of depositing a nano-layer onto the surface structuring, in accordance with some embodiments.

FIG. 7 is a schematic illustration of a method of depositing a nano-layer onto the surface structuring, in accordance with some embodiments.

FIG. 8 is a block diagram illustrating a method for surface structuring to increase emissivity, in accordance with some embodiments.

While the invention is subject to various modifications and alternative forms, specific embodiments thereof are shown by way of example in the drawings and the accompanying detailed description. It should be understood, however, that the drawings and detailed description are not intended to limit the invention to the particular embodiments. This disclosure is instead intended to cover all modifications, equivalents, and alternatives falling within the scope of the present invention as defined by the appended claims.

### V. DETAILED DESCRIPTION

One or more embodiments of the invention are described below. It should be noted that these and any other embodiments are exemplary and are intended to be illustrative of the invention rather than limiting. While the invention is widely applicable to different types of systems, it is impossible to include all of the possible embodiments and contexts of the invention in this disclosure. Upon reading this disclosure, many alternative embodiments of the present invention will be apparent to persons of ordinary skill in the art.

Being able to increase the emissivity of metal and non-metal surfaces, either flat or curved, is important to both military and commercial applications. High emissivity allows for applications in customized camouflage, optical sensing and imaging, thermal management, countermeasures, and improved solar cell efficiency just to name a few. Surface structuring with symmetrical geometry and high aspect ratio ablation of two-dimensional (2D) surface micro and nano structures is key in order to obtain high emissivity through a light trapping mechanism. The emissivity, εᵣ, of a sample with a certain roughness, Rₐ, is defined in Equation 1:

$${ɛ}_{r} = {[ 1 + ( \frac{1}{{ɛ}_{s}} - 1 ) R ]}^{- 1} , \qquad [ Equation 1 ]$$

where R=(1+1.25²π²n²Rₐ²)⁻¹ and n is a geometrical calibration factor related to the aspect ratio (depth/width of the light trapping geometry). A perfect black body in thermal equilibrium has an emissivity of one. Thus, by increasing the surface structuring, i.e. the surface roughness and aspect ratio, it is possible to increase the emissivity of the sample. Additionally, in order to protect the surface structuring against harsh environments, it important to either shape the microstructure to be less spiky and/or protect the microstructures by coating the surface structuring.

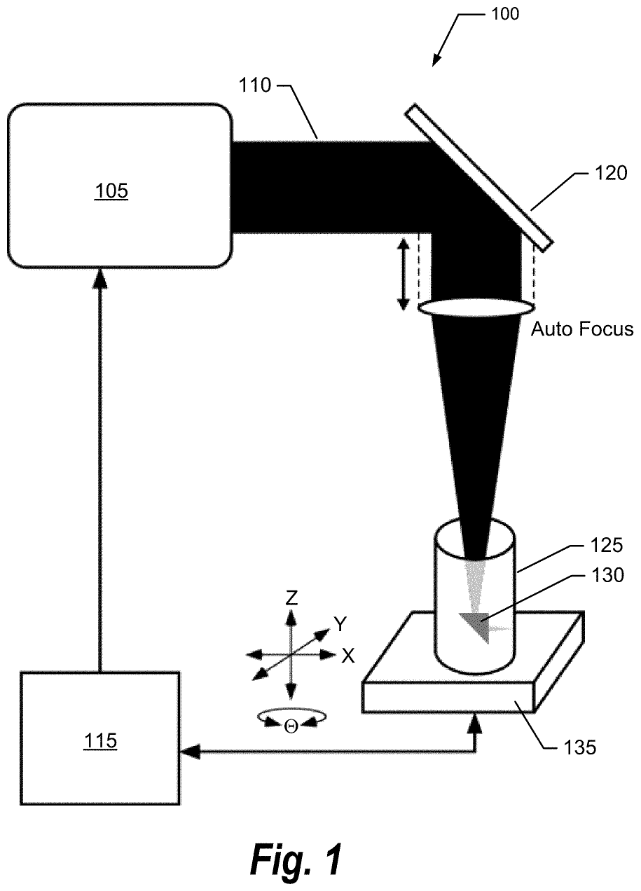

FIG. 1 is a schematic illustration of an apparatus for surface structuring to increase emissivity, in accordance with some embodiments.

In some embodiments, a femtosecond (fs) fiber laser based surface structuring system 100 comprises a high energy femtosecond fiber laser 105 configured to produce high energy, fs laser pulses 110. The laser pulses may comprise a substantially Gaussian beam profile with a pulse repetition rate (PRR) from about 0.1 MHz to 10 MHz, an average power of about 0.1 to 2000 W, a pulse width of about 100 fs to 1000 ps (1 ns), an energy from about 0.1 μJ to 1,000 μJ, and a wavelength between about 0.2 to 3 μm. Examples of femtosecond fiber lasers include but are not limited to Yb doped fiber laser at 1025-1100 nm and its harmonic generations to green and UV (ultra violet), Er doped fiber laser at 1525-1610 nm and its harmonic generations, Tm doped fiber laser at 1950-2050 nm, Ho doped fiber laser at 2050-2150 nm, and Er:ZBLAN fiber lasers at 2700-2900 nm. A computer 115 is used to control the PRR and the power of the high energy femtosecond fiber laser 105. The sample, whose emissivity is to be increased, may comprise planar as well as non-planar metals, semiconductors, ceramics, polymers, or glass surfaces. In addition, in order to protect the surface structuring resulting from the femtosecond fiber laser based processing, the surface of the sample may be coated with nano-powders of diamond, carbon, refractory metals, and/or ceramics such as tungsten, silicon carbide, zirconium carbide, tungsten carbide, etc. The high energy, fs laser pulse 110 is coupled into an autofocusing scanner 120 which scans and focuses the pulses 115 onto the sample 125 to be processed. The autofocusing scanner 120 may be controlled by the computer 115. In some embodiments, the autofocusing scanner comprises about a 0.5 m to about 1 m focal length. In some embodiments, the high energy, fs laser pulse is redirected onto the sample with an optical element such as a prism or mirror 130 in order to gain access to inner surfaces of the sample. The sample illustrated in FIG. 1 is a metal tube whose inner surface is being processed. It is possible to process the outer surface of the sample as well. The sample 125 may be positioned using a four degrees of freedom (4D) translation stage 135 that comprises an X, Y, Z translation with rotational adjustment in phi (Φ). The translation stage 135 may be controlled by the computer 115. The scanner 120 may be an acousto-optic type scanner (diffraction), a magnetic resonant scanner, a mechanical scanner (rotating mirror), or an electro-optic scanner, etc.

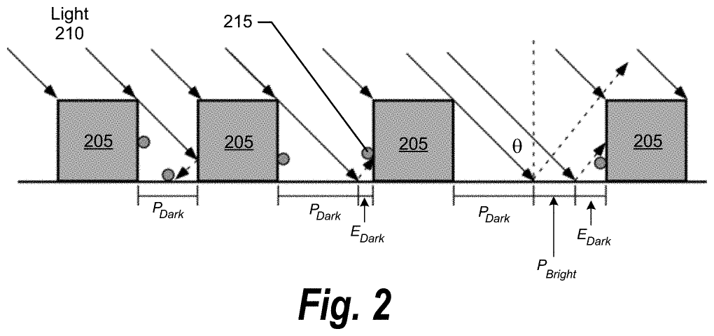

1¶201 FIG. 2 is a schematic diagram illustrating the light trapping mechanism resulting from the surface structuring to increase emissivity, in accordance with some embodiments.

For micro- and nano-surface structuring, fs fiber laser processing may be used to precisely modify the surface of the sample to obtain high aspect ratio surfaces features, i.e. micro spikes. Light trapping plays a significant role in increased emissivity, from a wide angle of view of the sample surface. Therefore, it is important to form sharp and high aspect ratio micro spikes 205 (pillars) in order to increase the absorbance of light 210. The nano structures 215 (grains) on the wall of the micro spikes 205 enhance the light trapping by not permitting the light to escape from the well formed between the micro spikes. FIG. 2 illustrates such a progressive light absorption improvement with various types of structures and micro spikes. When light 210 comes from a given angle, θ, those areas unblocked by the micro spikes, P_{Bright}, reflect light while blocked regions, P_{Dark}, show darkness. The nano structures 215 enhance the dark region, E_{Dark}, by blocking light which would otherwise be reflected if not for the nano structures on the surfaces of the sample. The creation of the micro spikes with or without nano structures may be written in one dimension or two dimensions on the surface of the sample.

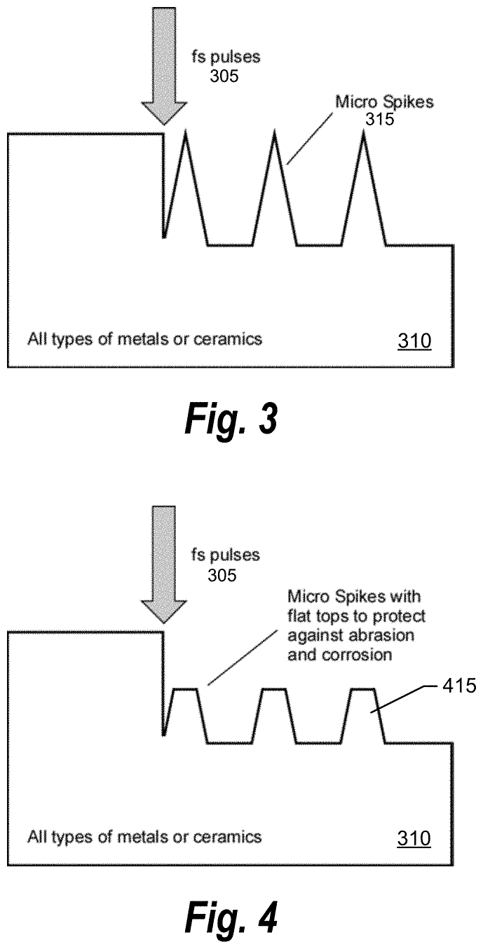

FIG. 3 is a schematic illustration of the surface structuring to increase emissivity, in accordance with some embodiments.

FIG. 4 is a schematic illustration of the surface structuring to increase emissivity, in accordance with some embodiments.

In order to increase emissivity of a sample, fs fiber laser pulses 305 are directed to a sample 310 comprising any type of metal, ceramic, or semiconductor materials. The resulting high peak intensity in the focal region ionizes the material of the sample and creates 2D micro- and nano-surface structures, micro spikes 315 on the surface of the sample, as illustrated in FIG. 3. In some embodiments, by controlling the scan speed, energy, pulse repetition rate (or frequency), and hatching spacing of the fs fiber laser pulses, it is possible to fabricate micro spikes with flat tops 415 as illustrated in FIG. 4. Micro spikes with flat tops provide the sample more protection against abrasion and corrosion. By fabricating wider (>10 μm spaced micro spikes) and deeper surface structures (>15 μm tall quasi-ordered array of micro spikes) with higher aspect ratios (>1) to accommodate longer wavelengths, it is possible to achieve over 99% absorption from the UV to the far IR region (8 μm to 12 μm) and thus higher emissivity. By controlling the aspect ratio and surface roughness of the micro spikes it is possible to obtain a desired emissivity of the sample.

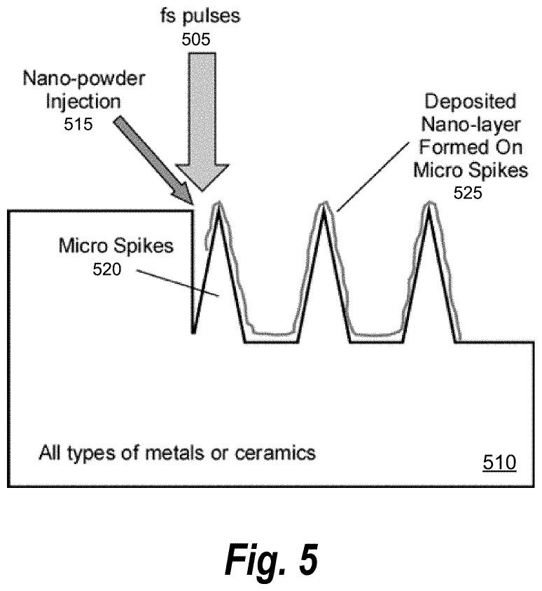

FIG. 5 is a schematic illustration of the surface structuring and concurrent coating to increase emissivity and resistance to harsh environments, in accordance with some embodiments.

In some embodiments, it is possible to form micro spike surface structures and deposit a nano-layer onto the micro spikes in a single processing step. The spikes can be sharp spikes or flat top spikes as shown in FIG. 3 and FIG. 4. The nano or micro layer coated on those spikes can help increase the emissivity and/or protection against harsh environments (such as abrasion, erosion, corrosion). In such an embodiment, fs fiber laser pulses 505 are directed to a sample 510 comprising any type of metal or ceramic while concurrently injecting a nano-powder 515 in the region of the sample where the fs fiber laser pulses are being directed to in order to fabricate 2D micro- and nano-surface structures, micro spikes 520, having a deposited nano-layer 525 on top of the micro spikes. The injected nano-powder may comprise diamond, carbon, refractory metals, and/or ceramics such as tungsten, silicon carbide, zirconium carbide, tungsten carbide, etc. The deposition of the nano-layer makes it possible for the sample to withstand harsh environments.

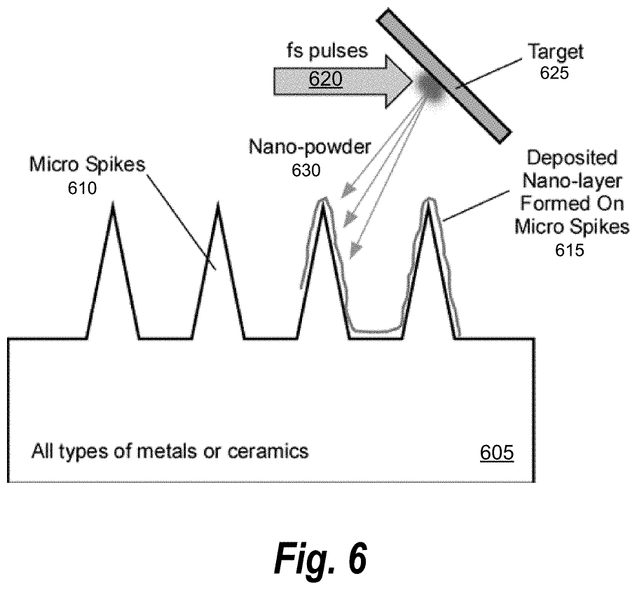

FIG. 6 is a schematic illustration of a method of depositing a nano-layer onto the surface structuring, in accordance with some embodiments.

In some embodiments, if the sample 605 already comprises surface structures, micro spikes 610, it is possible to deposit a nano-layer 615 onto the surface structures in order to improve the resistance of the sample to harsh environments. In such an embodiment, fs fiber laser pulses 620 are directed to a target 625 comprising diamond, carbon, refractory metals, and/or ceramics such as tungsten, silicon carbide, zirconium carbide, tungsten carbide, etc. which results in the ejection of nano-powder 630 from the target and onto the sample. The spikes can be sharp spikes or flat top spikes as shown in FIG. 3 and FIG. 4. The nano or micro layer coated on those spikes can help increase the emissivity and/or protection against harsh environments (such as abrasion, erosion, corrosion).

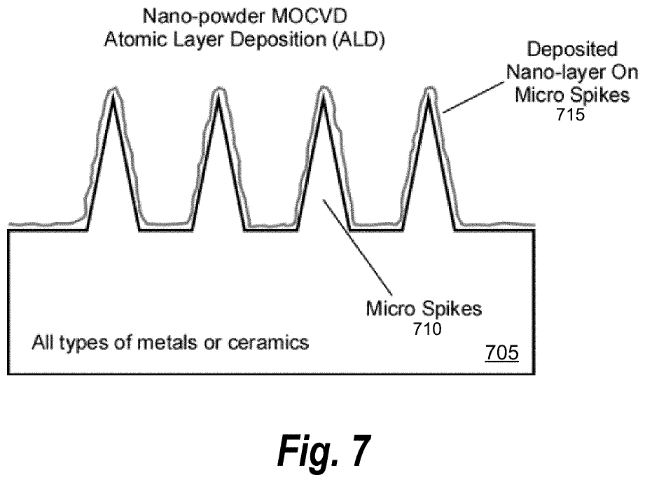

FIG. 7 is a schematic illustration of a method of depositing a nano-layer onto the surface structuring, in accordance with some embodiments.

In some embodiments, if the sample 705 already comprises surface structures, micro spikes 710, it is possible to deposit a nano-layer 715 onto the surface structures in order to improve the resistance of the sample to harsh environments. In such an embodiment, metal-organic chemical vapor deposition (MOCVD) is used to deposit atoms layer by layer onto the sample. Atomic layer deposition (ALD) is another alternative. The resulting nano-layer may comprise diamond, carbon, refractory metals, and/or ceramics such as tungsten, silicon carbide, zirconium carbide, tungsten carbide, etc. The spikes can be sharp spikes or flat top spike as shown in FIG. 3 and FIG. 4. The nano or micro layer coated on those spikes can help increase the emissivity and/or protection against harsh environment (such as abrasion, erosion, corrosion).

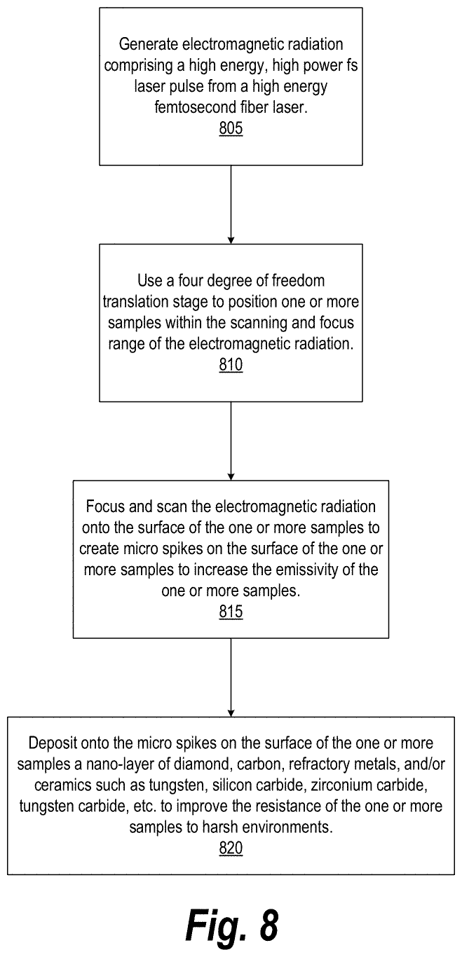

FIG. 8 is a block diagram illustrating a method for surface structuring to increase emissivity, in accordance with some embodiments.

In some embodiments, processing begins at step 805 where a high energy femtosecond fiber laser is used to generate electromagnetic radiation comprising a high energy, high power fs laser pulse. The electromagnetic radiation comprises a PRR from about 0.1 MHz up to 10 MHz, an average power of about 0.1 to 2000 W, a pulse width of about 100 fs to 1000 ps, an energy from about 0.1 μJ to 1,000 μJ, and a wavelength between about 0.2 to 3 μm. Examples of femtosecond fiber lasers include but are not limited to Yb doped fiber laser at 1025-1100 nm and its harmonic generations to green and UV, Er doped fiber laser at 1525-1610 nm and its harmonic generations, Tm doped fiber laser at 1950-2050 nm, Ho doped fiber laser at 2050-2150 nm, and Er:ZBLAN fiber lasers at 2700-2900 nm. For curved surfaces, a 3D AutoCAD file related to the surface is loaded into the computer for programming. At step 810, a four degree of freedom translation stage is used to position one or more samples within the scanning and focus range of the electromagnetic radiation. At step 815, the electromagnetic radiation is focused and scanned onto the surface of the one or more samples. The resulting high peak intensity in the focal region ionizes the material of the one or more samples and creates 2D micro- and nano-surface structures, micro spikes. In some embodiments, the micro spikes are fabricated with flat tops in order to protect the one or more samples from abrasion and corrosion. In some embodiments, the micro spikes are fabricated with grains on the micro spikes. Next at step 820, in some embodiments, the micro spikes are subsequently coated with a nano-powder of diamond, carbon, refractory metals, and/or ceramics such as tungsten, silicon carbide, zirconium carbide, tungsten carbide, etc. to improve the resistance of the one or more samples to harsh environments. Alternatively, in some embodiments, the micro spikes are simultaneously coated during creation of the micro spikes by the injection of nano-powders concurrently with the fs laser pulses.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

The benefits and advantages that may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed within the following claims.

1. A method for surface structuring to increase emissivity of one or more samples comprising:
generating electromagnetic radiation from a femtosecond fiber laser, wherein the electromagnetic radiation comprises a wavelength, a pulse repetition rate, a pulse width, a pulse energy, and an average power;
coupling the electromagnetic radiation from the femtosecond fiber laser to an autofocusing scanner, wherein the autofocusing scanner is configured to scan and focus the electromagnetic radiation onto the one or more samples; and
using a computer to adjust the pulse repetition rate and the pulse energy of the femtosecond fiber laser and to control the autofocusing scanner to scan and focus the electromagnetic radiation onto the one or more samples to fabricate micro spikes onto the surface of the one or more samples in order to increase the emissivity of the one or more samples.

2. The method of claim 1, wherein the micro spikes comprise flat tops.

3. The method of claim 1, wherein the micro spikes comprise grains on the micro spikes.

4. The method of claim 1 further comprising controlling aspect ratios and surface roughnesses of the micro spikes to obtain a desired emissivity.

5. The method of claim 1 further comprising using the computer to control a four degree of freedom translation stage to position the one or more samples within the scanned and focused electromagnetic radiation.

6. The method of claim 1 further comprising depositing a nano-layer onto the micro spikes.

7. The method of claim 6, wherein the nano-layer comprises at least one of diamond, carbon, refractory metal, and ceramic.

8. The method of claim 6, wherein depositing the nano-layer onto the micro spikes comprises concurrently injecting a nano-powder in a region of the one or more samples where the scanned and focused electromagnetic radiation are directed during fabrication of the micro spikes.

9. The method of claim 6, wherein depositing the nano-layer onto the micro spikes comprises directing the electromagnetic radiation onto a target to eject nano-powder from the target and onto the one or more samples.

10. The method of claim 6, wherein depositing the nano-layer onto the micro spikes comprises using an MOCVD or ALD to deposit atoms layer by layer.

11. The method of claim 1, wherein the one or more samples comprise a planar surface and/or a non-planar surface.

12. The method of claim 1 further comprising using an optical element to redirect the electromagnetic radiation onto inner surfaces of the one or more samples.

13. The method of claim 1, wherein the femtosecond fiber laser comprises at least one of a Yb doped fiber laser, an Er doped fiber laser, a Tm doped fiber laser, a Ho doped fiber laser, and an Er:ZBLAN fiber laser.

14. An apparatus for surface structuring to increase emissivity of one or more samples comprising:
a femtosecond fiber laser configured to generate electromagnetic radiation comprising a wavelength, a pulse repetition rate, a pulse width, a pulse energy, and an average power;
an autofocusing scanner configured to receive the electromagnetic radiation from the femtosecond fiber laser and to scan and focus the electromagnetic radiation onto the one or more samples; and
a computer configured to adjust the pulse repetition rate and the pulse energy of the femtosecond fiber laser and to control the autofocusing scanner to scan and focus the electromagnetic radiation onto the one or more samples to fabricate micro spikes onto the surface of the one or more samples in order to increase the emissivity of the one or more samples.

15. The apparatus of claim 14, wherein the micro spikes comprise flat tops.

16. The apparatus of claim 14, wherein the micro spikes comprise grains on the micro spikes.

17. The apparatus of claim 14, further comprising controlling aspect ratios and surface roughnesses of the micro spikes to obtain a desired emissivity.

18. The apparatus of claim 14 further comprising a four degree of freedom translation stage configured to position the one or more samples within the scanned and focused electromagnetic radiation.

19. The apparatus of claim 14, wherein the micro spikes are coated with a nano-layer.

20. The apparatus of claim 19, wherein the nano-layer comprises at least one of diamond, carbon, refractory metal, and ceramic.

21. The apparatus of claim 19 further comprising a nano-powder injector, wherein the nano-powder injector is configured to inject nano-powder in a region of the one or more samples where the scanned and focused electromagnetic radiation are directed during fabrication of the micro spikes to coat the nano-layer onto the micro spikes.

22. The apparatus of claim 19 further comprising a target, wherein the target is configured to eject nano-powder from the target and onto the one or more samples when the electromagnetic radiation is scanned and focused onto the target to coat the nano-layer onto the micro spikes.

23. The apparatus of claim 19 further comprising an MOCVD or ALD, wherein the MOCVD and ALD are configured to deposit atoms layer by layer to coat the nano-layer onto the micro spikes.

24. The apparatus of claim 14, wherein the one or more samples comprise a planar surface and/or a non-planar surface.

25. The apparatus of claim 14 further comprising an optical element, wherein the optical element is configured to redirect the electromagnetic radiation onto inner surfaces of the one or more samples.

26. The apparatus of claim 14, wherein the femtosecond fiber laser comprises at least one of a Yb doped fiber laser, an Er doped fiber laser, a Tm doped fiber laser, a Ho doped fiber laser, and an Er:ZBLAN fiber laser.
